(19) United States
(12) Patent Application Publication
(10) Pub. No.: US 2026/0144068 A1
(43) Pub. Date: May 21, 2026

(54) SEMICONDUCTOR PACKAGE AND MANUFACTURING METHOD FOR THE SAME

(71) Applicant: Samsung Electronics Co., Ltd., Suwon-si (KR)

(72) Inventors: HyeonGyu Lee, Suwon-si (KR); Yiseul Han, Suwon-si (KR)

(73) Assignee: Samsung Electronics Co., Ltd., Suwon-si (KR)

(21) Appl. No.: 19/086,788

(22) Filed: Mar. 21, 2025

(30) Foreign Application Priority Data
Nov. 19, 2024 (KR) 10-2024-0165646

(51) Int. Cl. H01L 23/00; H01L 21/56; H01L 21/683; H01L 23/31; H01L 23/544; H01L 25/065; H10B 80/00; H10D 80/30

(52) U.S. Cl. CPC H10W 42/121; H10W 74/121; H10W 90/00; H10B 80/00; H10D 80/30; H10P 72/74; H10W 46/00; H10W 46/301; H10W 72/0198; H10W 72/865; H10W 72/884; H10W 74/01; H10W 90/24; H10W 90/732; H10W 90/734; H10W 90/754

(57) ABSTRACT

The present disclosure provides, in some embodiments, a semiconductor package which includes a first semiconductor chip; a first support film that is disposed side by side with the first semiconductor chip; a second semiconductor chip that is disposed on the first semiconductor chip so as to be misaligned with the first semiconductor chip and includes a first overhang region which is supported by the first support film; a second support film that is disposed on the first support film side by side with the second semiconductor chip; an encapsulant that covers at least a portion of each of the first semiconductor chip, the second semiconductor chip, the first support film, and the second support film; and a redistribution structure that is disposed on the encapsulant and electrically connected to the first semiconductor chip and the second semiconductor chip.

### CROSS-REFERENCE TO RELATED APPLICATIONS

This present application claims priority to and the benefit under 35 U.S.C. § 119(a)-(d) of Korean Patent Application No. 10-2024-0165646 filed in the Korean Intellectual Property Office on Nov. 19, 2024, the entire disclosure of which is incorporated herein by reference.

### FIELD

The present disclosure relates to a semiconductor package and a manufacturing method for the same.

### BACKGROUND

In the semiconductor package field, stack chip package technology is known in that a plurality of semiconductor chips is vertically stacked and integrated in one package.

### SUMMARY

Some aspects of the present disclosure are to provide a semiconductor package and a manufacturing method for the same, in which the semiconductor package is capable of preventing a stacked semiconductor chip from warping and/or cracking.

The present disclosure provides, in some embodiments, a semiconductor package which includes a first semiconductor chip, a first support film that is disposed side by side with the first semiconductor chip, a second semiconductor chip that is disposed on the first semiconductor chip so as to be misaligned with the first semiconductor chip, and includes a first overhang region which is supported by the first support film, a second support film that is disposed on the first support film side by side with the second semiconductor chip, an encapsulant that covers at least a portion of each of the first semiconductor chip, the second semiconductor chip, the first support film, and the second support film, and a redistribution structure that is disposed on the encapsulant and electrically connected to the first semiconductor chip and the second semiconductor chip.

The present disclosure provides, in some embodiments, a semiconductor package which includes a first semiconductor chip, a first adhesive member that is attached to a lower surface of the first semiconductor chip, a second semiconductor chip that is disposed on an upper surface of the first semiconductor chip so as to be misaligned with the first semiconductor chip and includes an overhang region protruding outwardly from the first semiconductor chip, a support film that has a lower surface coplanar with a lower surface of the first adhesive member and supports the overhang region of the second semiconductor chip, a second adhesive member that is disposed between the first semiconductor chip and the second semiconductor chip so as to be disposed over the support film and the first semiconductor chip, and attaches the second semiconductor chip to the first semiconductor chip and the support film, a first encapsulant that covers at least a portion of each of the first semiconductor chip, the second semiconductor chip, the support film, the first adhesive member, and the second adhesive member, and a first redistribution structure that is disposed on the first encapsulant and is electrically connected to each of the first semiconductor chip and the second semiconductor chip.

The present disclosure provides, in some embodiments, a semiconductor package comprising: a first semiconductor chip; a first support film that is disposed laterally adjacent to the first semiconductor chip; a second semiconductor chip that is disposed in part on the first semiconductor chip and in part on the first support film; a second support film that is disposed laterally adjacent to the second semiconductor chip; and a first wiring layer that is electrically connected to the first semiconductor chip and a second wiring layer that is electrically connected to the second semiconductor chip.

The present disclosure provides, in some embodiments, a semiconductor package manufacturing method which includes a step of disposing a first semiconductor chip on a carrier substrate, a step of disposing a first support film side by side with the first semiconductor chip on the carrier substrate, a step of disposing a second semiconductor chip on the first semiconductor chip so as to be misaligned with the first semiconductor chip such that the second semiconductor chip has a first overhang region which is supported by the first support film, a step of disposing a second support film side by side with the second semiconductor chip on the first support film, a step of encapsulating the first semiconductor chip, the second semiconductor chip, the first support film, and the second support film by an encapsulant, and a step of forming a redistribution structure on the encapsulant so as to be electrically connected to the first semiconductor chip and the second semiconductor chip.

The semiconductor package manufacturing method may further include: a step of disposing a third semiconductor chip on the second semiconductor chip so as to be misaligned with the second semiconductor chip such that the third semiconductor chip has a second overhang region which is supported by the second support film. In the step of disposing the first support film, a thickness of the first support film may be equal to or larger than a sum of a thickness of the first semiconductor chip and a thickness of a first adhesive member. In the step of disposing the second semiconductor chip, the second semiconductor chip may press the first support film. In some embodiments, the second support film may be attached directly to the first support film.

According to some aspects of the present disclosure, it is possible to provide a semiconductor package and a manufacturing method for the same capable of preventing a stacked semiconductor chip from warping and preventing a semiconductor chip from cracking.

### BRIEF DESCRIPTION OF THE DRAWINGS

FIG. 1 is a cross-sectional view of a semiconductor package according to some embodiments.

FIG. 2 is a cross-sectional view of a semiconductor package according to some embodiments.

FIG. 3 is a cross-sectional view of a semiconductor package according to some embodiments.

FIG. 4 is a cross-sectional view of a semiconductor package according to some embodiments.

FIG. 5 is a cross-sectional view of a semiconductor package according to some embodiments.

FIG. 6 is a cross-sectional view of a semiconductor package according to some embodiments.

FIGS. 7 to 16 are views illustrating a process of manufacturing a semiconductor package according to some embodiments.

### DETAILED DESCRIPTION

In the following detailed description, only certain embodiments of the present disclosure have been shown and described, simply by way of illustration. The present disclosure can be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto. In the drawings, the thickness of layers, films, panels, regions, etc., are exaggerated for clarity. Further, in the drawings, for understanding and ease of description, the thickness of some layers and areas is exaggerated.

Throughout this specification, when a part is referred to as being “connected” to another part, it may be directly connected to the other part or may be connected to the other part indirectly with any other elements interposed therebetween. From a similar point of view, when a part is referred to as being “connected” to another part, it may be physically connected to the other part or may be electrically connected to the other part.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, in the entire specification, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

Furthermore, throughout this specification, the ordinal numbers such as first, second, or the like are used to distinguish an element from other elements identical or similar to the corresponding element, and are not necessarily intended to indicate a particular element. Accordingly, an element termed as a first element in a part of this specification may be termed as a second element in other parts of this specification.

Further, throughout this specification, elements expressed in the singular forms are intended to include the plural forms as well unless the context clearly indicates otherwise.

Furthermore, throughout this specification, expressions related to directions, such as upper surfaces, upper sides, upper portions, lower surfaces, lower sides, and lower portions are stated with reference to the drawings to aid in the description and understanding.

Hereinafter, semiconductor packages according to embodiments of the present disclosure will be described with reference to the drawings.

In a stack chip package structure, semiconductor chips are stacked so as to be misaligned such that their connection pads are exposed and each semiconductor chip has an overhang region protruding toward a side surface of another semiconductor chip disposed below it.

During a semiconductor package manufacturing process (for example, an encapsulant forming process), stress may be applied to the overhang region of a semiconductor chip, and the applied stress may cause the semiconductor chip to warp or cause the semiconductor chip to crack.

According to some embodiments, the overhang region of a semiconductor chip can be supported by a film. The inventors have appreciated that such a film can prevent bending and cracking due to applied stress, as identified herein.

Each film may be disposed side by side with a corresponding semiconductor chip. When a first semiconductor chip has a second semiconductor chip disposed thereon so as to be misaligned with the first semiconductor chip, a first film side by side with the first semiconductor chip can support an overhanging region of the second semiconductor chip. The material of the film may have resiliency. As described herein, the inventors have developed a semiconductor package with reduced effects due to stress by incorporating a supporting film.

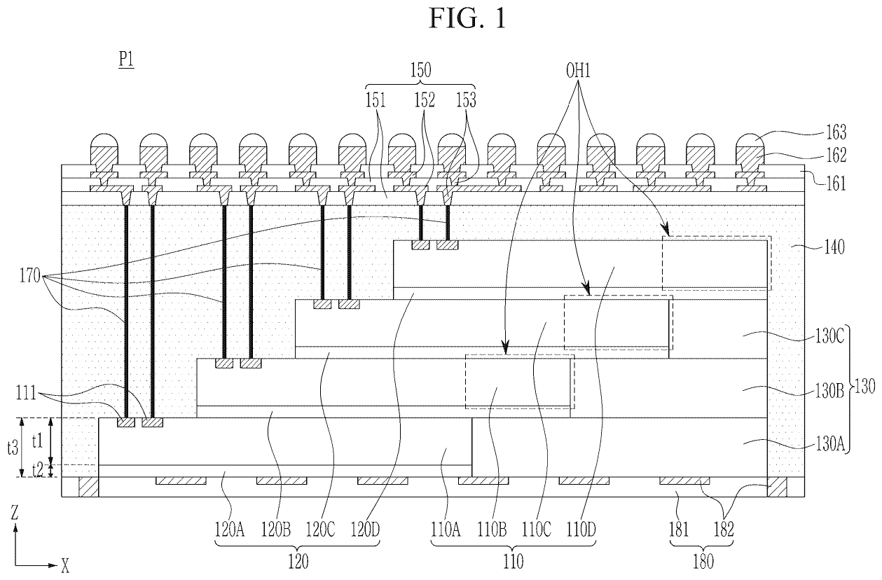

FIG. 1 is a cross-sectional view of a semiconductor package according to some embodiments.

A semiconductor package P1 may include semiconductor chips 110 including connection pads 111, adhesive members 120, support films 130, an encapsulant 140, a redistribution structure 150, a passivation layer 161, conductive pillars 162, conductive bumps 163, conductive wires 170, and an alignment structure 180.

The semiconductor chips 110 may be stacked in a Z direction (Z). For example, the semiconductor chips 110 may include a first semiconductor chip 110A, a second semiconductor chip 110B disposed on the first semiconductor chip 110A, a third semiconductor chip 110C disposed on the second semiconductor chip 110B, and a fourth semiconductor chip 110D disposed on the third semiconductor chip 110C. The number of semiconductor chips 110 stacked is not particularly limited, and may be more or less than shown in the drawing.

Each semiconductor chip 110 may be disposed such that a surface with a connection pad 111 disposed thereon faces upward. Each semiconductor chip 110 may be disposed on the upper surface of another semiconductor chip 110 disposed below it so as to be misaligned such that the connection pad 111 of another semiconductor chip 110 disposed below it is exposed. Accordingly, each semiconductor chip 110 may include an overhang region OH1 protruding from a side surface of another semiconductor chip 110 disposed below it. For example, the second semiconductor chip 110B may be disposed on the upper surface of the first semiconductor chip 110A so as to be misaligned such that the connection pad 111 of the first semiconductor chip 110A is exposed and may include an overhang region OH1 protruding from a side surface of the first semiconductor chip 110A. The second semiconductor chip 110B may be disposed in part on the first semiconductor chip 110A and in part on a first support film 130A. Further, the third semiconductor chip 110C may be disposed on the upper surface of the second semiconductor chip 110B so as to be misaligned such that the connection pad 111 of the second semiconductor chip 110B is exposed and may include an overhang region OH1 protruding from a side surface of the second semiconductor chip 110B. Furthermore, the fourth semiconductor chip 110D may be disposed on the upper surface of the third semiconductor chip 110C so as to be misaligned such that the connection pad 111 of the third semiconductor chip 110C is exposed, and may include an overhang region OH1 protruding from a side surface of the third semiconductor chip 110C.

The thickness t1 of each semiconductor chip 110 may be within a range from 35 μm to 55 μm. For example, the thickness t1 of a semiconductor chip 110 may be within a range from 40 μm to 50 μm.

Each semiconductor chip 110 may be a memory chip. The memory chip may include one or more of dynamic random access memory (DRAM) chips, static random access memory (SRAM) chips, flash memory chips, high bandwidth memory (HBM) chips, read-only memory (ROM) chips, and magnetic random access memory (MRAM) chips. However, the type of each semiconductor chip 110 is not limited to a memory chip, and each semiconductor chip 110 may be another type of semiconductor chip such as a logic chip, a controller chip, or an application-specific integrated circuit (ASIC).

To the lower surfaces of the individual semiconductor chips 110, the adhesive members 120 for attaching the semiconductor chips 110 to other components may be attached. For example, the adhesive members 120 may include a first adhesive member 120A for attaching the first semiconductor chip 110A to the alignment structure 180, a second adhesive member 120B for attaching the second semiconductor chip 110B to the first semiconductor chip 110A, a third adhesive member 120C for attaching the third semiconductor chip 110C to the second semiconductor chip 110B, and a fourth adhesive member 120D for attaching the fourth semiconductor chip 110D to the third semiconductor chip 110C.

As the overhang region OH1 of a semiconductor chip 110 is disposed on a support film 130, the adhesive member 120 attached to the semiconductor chip 110 may be disposed over the upper surfaces of another semiconductor chip 110 and a support film 130 disposed below it and attach the semiconductor chip 110 to them. For example, the second adhesive member 120B may be disposed over the upper surfaces of the first semiconductor chip 110A and a first support film 130A and may attach the second semiconductor chip 110B to them. Further, the third adhesive member 120C may be disposed over the upper surfaces of the second semiconductor chip 110B and a second support film 130B and may attach the third semiconductor chip 110C to them. Furthermore, the fourth adhesive member 120D may be disposed over the upper surfaces of the third semiconductor chip 110C and a third support film 130C and may attach the fourth semiconductor chip 110D to them.

The thickness t2 of each adhesive member 120 may be within a range from 5 μm to 15 μm. For example, the thickness t2 of each adhesive member 120 may be within a range from 6 μm to 14 μm, from 7 μm to 13 μm, from 8 μm to 12 μm, or from 9 μm to 11 μm, or may be about 10 μm.

Each support film 130 may support the overhang region OH1 of a semiconductor chip 110 disposed thereon. Each support film 130 may be disposed side by side with (or laterally adjacent to) a semiconductor chip 110 (which may include situations in which there is an intervening component in some embodiments) on another support film 130 or the alignment structure 180 disposed below it. For example, the support films 130 may include the first support film 130A which is disposed side by side with the first semiconductor chip 110A and supports the overhang region OH1 of the second semiconductor chip 110B, the second support film 130B which is disposed side by side with the second semiconductor chip 110B on the first support film 130A and supports the overhang region OH1 of the third semiconductor chip 110C, and the third support film 130C which is disposed side by side with the third semiconductor chip 110C on the second support film 130B and supports the overhang region OH1 of the fourth semiconductor chip 110D. As described above, to the lower surface of a semiconductor chip 110 which is disposed side by side with a support film 130, an adhesive member 120 may be attached.

Each support film 130 may be attached side by side with a semiconductor chip 110 with an adhesive member 120 attached thereto. Accordingly, each support film 130 may have a lower surface substantially coplanar with the lower surface of an adhesive member 120.

As will be described, each support film 130 may be pressed by a semiconductor chip 110 which is disposed thereon. Accordingly, each support film 130 may have an upper surface substantially coplanar with the upper surface of a semiconductor chip 110 which is disposed side by side with the support film 130.

The thickness t3 of each support film 130 may become the same as or very similar to the sum of the thickness of a semiconductor chip 110 disposed side by side with the support film and the thickness of the adhesive member 120 attached to the lower surface of the semiconductor chip 110, due to pressurization by another semiconductor chip 110. For example, the thickness t3 of each support film 130 may be within a range from 40 μm to 70 μm, or from 50 μm to 60 μm.

As for the widths of the support films 130, the lower a support film is disposed, the wider it may be. In the present disclosure, a width may refer to the width in an X direction (X), which is the direction in which the semiconductor chips 110 are misaligned, in a plan view. Since the lower a support film 130 is disposed, the wider it is, each support film 130 may stably support the overhang region OH1 of a semiconductor chip 110 and another support film 130 which are disposed thereon.

At least one of the support films 130 may overlap the uppermost semiconductor chip 110D. In other words, at least one of the support films 130 may overlap the edge of the uppermost semiconductor chip 110D or may be disposed on the inner side relative to the edge of the uppermost semiconductor chip, in a plan view. For example, the entire region of each of the first support film 130A, the second support film 130B, and the third support film 130C may overlap the uppermost semiconductor chip 110D. Since each support film 130 overlaps the uppermost semiconductor chip 110D, it is possible to prevent the size of the semiconductor package from being increased due to the support film 130.

Each support film 130 may contain an insulating material. For example, at least one of the support films 130 may include Ajinomoto build-up film (ABF).

Each support film 130 may have the property of adhering such that it can be attached directly to another component, such as the alignment structure 180 or another support film 130, without a separate adhesive member, and an additional process such as curing is not required. Further, each support film 130 may have the property of being easily deformed, so as to be processed to an appropriate size depending on design and attached to another component. Furthermore, each support film 130 may be easily attached to a target position without a significant error. In summary, each support film 130 may be introduced into the semiconductor package in a simple manner.

The encapsulant 140 may cover at least a portion of each of the semiconductor chips 110, the adhesive members 120, the support films 130, and the conductive wires 170. As a semiconductor chip 110 with an adhesive member 120 attached thereon and a support film 130 are attached to the upper surface of the alignment structure 180, side by side, and are encapsulated by the encapsulant 140, the lower surface of the encapsulant 140 may be substantially coplanar with the lower surface of each of the lowermost adhesive member 120A and the lowermost support film 130A.

The redistribution structure 150 may be disposed on the encapsulant 140 and electrically connected to each semiconductor chip 110. The redistribution structure 150 may be in contact with the encapsulant 140.

In the depicted embodiment, the redistribution structure 150 may be disposed on the upper surface of the encapsulant 140 so as to face the upper surfaces of the semiconductor chips 110 with the connection pads 111 disposed thereon.

The redistribution structure 150 may include insulating layers 151, wiring layers 152, and vias 153.

The insulating layer 151 may be formed of an insulating material, and may use, for example, a thermosetting resin such as polyimide, a thermoplastic resin such as epoxy, a photo-imageable dielectric (PID) material which is a photosensitive resin, etc. The insulating layers 151 may have boundaries to each other or may not have visible boundaries.

Each wiring layer 152 may be disposed on an insulating layer 151. Each wiring layer 152 may perform various functions depending on the design, and may include wiring patterns for performing various functions, such as a signal pattern, a power pattern, a ground pattern, etc. Further, the uppermost wiring layer of the wiring layers 152 may include pads which are connected to the conductive pillars 162 and/or the conductive bumps 163.

Each via 153 may pass through an insulating layer 151 and connect wiring layers 152 disposed in different layers to each other, or connect a wiring layer 152 to a conductive wire 170. Each wiring layer (e.g., formed in a redistribution structure) may be connected to each semiconductor chip or to a respective semiconductor chip (e.g., a first wiring layer may be electrically connected to the first semiconductor chip and a second wiring layer may be electrically connected to the second semiconductor chip). Each via 153 may have various shapes such as a tapered shape which narrows from one side toward the other side, a cylindrical shape, etc.

As the materials of the wiring layers 152 and the vias 153, a conductive material may be used, and, for example, aluminum (Al), copper (Cu), gold (Au), platinum (Pt), silver (Ag), tin (Sn), chromium (Cr), palladium (Pd), or an alloy of two or more of them may be used.

The passivation layer 161 may be disposed on the redistribution structure 150 and protect it. For example, the passivation layer 161 may be disposed on the uppermost insulating layer 151 and have openings which expose the pads of the uppermost wiring layer 152. The passivation layer 161 may be formed of an insulating material such as a solder resist.

The conductive pillars 162 and the conductive bumps 163 may be disposed on the redistribution structure 150. The conductive pillars 162 may connect the redistribution structure 150 and the conductive bumps 163. In some embodiments, the conductive pillars 162 may be omitted, and in this case, the conductive bumps 163 may be connected directly to the redistribution structure 150. As the material of each of the conductive pillars 162 and the conductive bumps 163, a conductive material may be used, and, for example, the conductive pillars 162 may be formed of copper (Cu), and the conductive bumps 163 may be formed of solder which is an alloy of silver (Ag) and tin (Sn).

Each conductive wire 170 may be embedded in the encapsulant 140 and may electrically connect the connection pad 111 of a semiconductor chip 110 to the redistribution structure 150. Each conductive wire 170 may be a vertical conductive wire extending in the Z direction (Z). As the material of the conductive wires 170, a conductive material such as copper (Cu), aluminum (Al), silver (Ag), gold (Au), or nickel (Ni) may be used.

The alignment structure 180 may provide the alignment positions of the semiconductor chips 110. The alignment structure 180 may be disposed to overlap the lowermost adhesive member 120A, the lowermost support film 130A, and the encapsulant 140. The alignment structure 180 may include an insulating layer (for example, a polyimide layer) 181 and conductive patterns (for example, copper patterns) 182. In some embodiments, the alignment structure 180 may be removed or omitted, and may not exist in the semiconductor package.

Meanwhile, during the semiconductor package manufacturing process (for example, the encapsulant forming process), when stress is applied to the overhang region of a semiconductor chip, the semiconductor chip may warp or cracks may occur in the semiconductor chip. According to the present disclosure, the overhang region of each semiconductor chip may be supported by a support film such that stress which is applied to the semiconductor chip during the semiconductor package manufacturing process is distributed. Accordingly, it is possible to prevent a problem in which a semiconductor chip is warped or cracks occur in a semiconductor chip due to stress which is applied to the semiconductor chip.

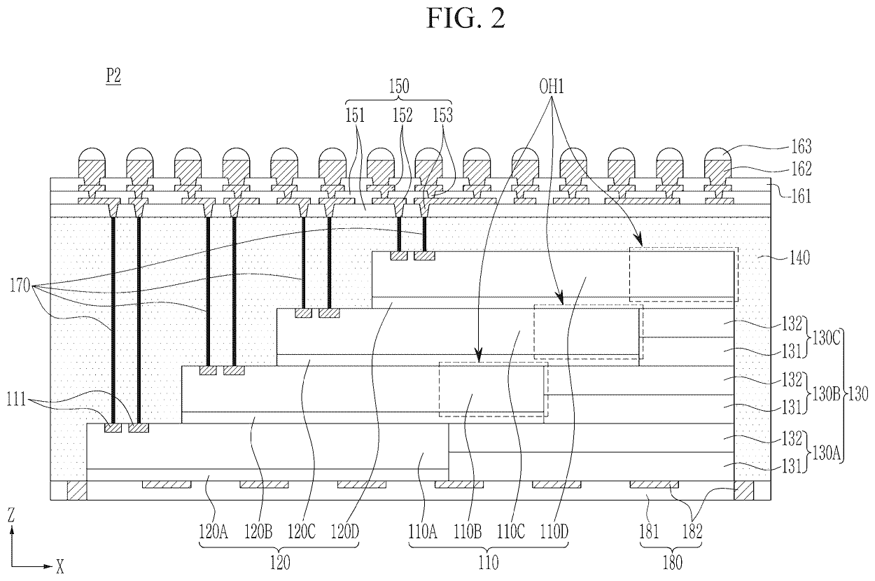

FIG. 2 is a cross-sectional view of a semiconductor package according to some embodiments.

As compared to the semiconductor package P1, each support film 130 of a semiconductor package P2 may be a multi-layer film including a plurality of film layers 131 and 132 stacked. For example, each support film 130 may include a first film layer 131 and a second film layer 132. When the thicknesses of the individual film layers 131 and 132 are thin, in order to provide a sufficient thickness capable of supporting the overhang region OH1 of each semiconductor chip 110, each support film 130 may consist of a plurality of layers.

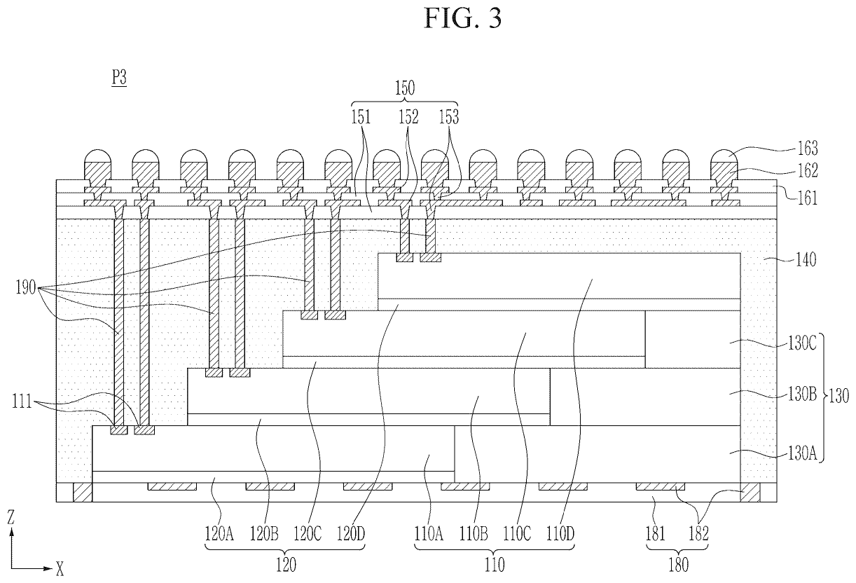

FIG. 3 is a cross-sectional view of a semiconductor package according to some embodiments.

As compared to the semiconductor package P1, in a semiconductor package P3, the connection pad 111 of each semiconductor chip 110 may be electrically connected to the redistribution structure 150 through a conductive post 190 embedded in the encapsulant 140. The conductive post 190 may have a larger diameter than the conductive wires 170. As the material of the conductive post 190, a conductive material such as copper (Cu), aluminum (AI), silver (Ag), gold (Au), or nickel (Ni) may be used.

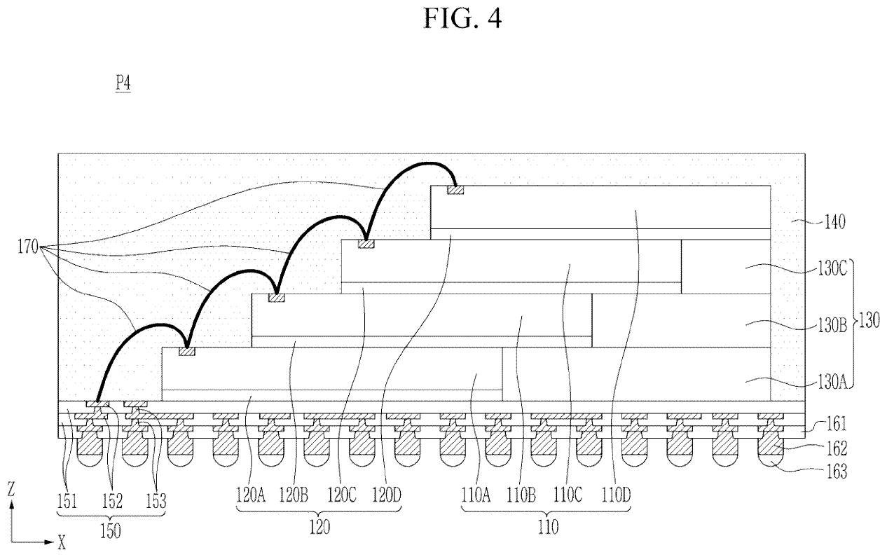

FIG. 4 is a cross-sectional view of a semiconductor package according to some embodiments.

As compared to the semiconductor package P1, in a semiconductor package P4, the redistribution structure 150 may be disposed on the lower surface of the encapsulant 140 so as to face the lower surfaces of the semiconductor chips 110 which are the opposite surfaces to the surfaces with the connection pads 111 of the semiconductor chips 110 disposed thereon. The connection pad 111 of each semiconductor chip 110 and the redistribution structure 150 may be connected by a conductive wire 170 extending from the upper surface of the semiconductor chip 110 to the upper surface of the redistribution structure 150.

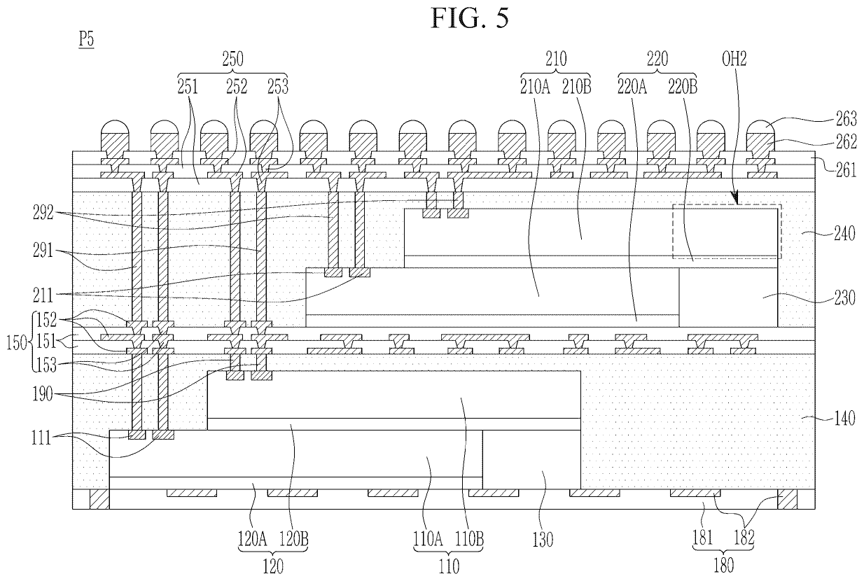

FIG. 5 is a cross-sectional view of a semiconductor package according to some embodiments.

As compared to the semiconductor package P1, a semiconductor package P5 may further include at least one first additional semiconductor chip 210 disposed on the redistribution structure 150, a first additional encapsulant 240 which covers at least a portion of the first additional semiconductor chip 210, and a first additional redistribution structure 250 disposed on the first additional encapsulant 240.

The descriptions of insulating layers 151, wiring layers 152, vias 153, first semiconductor chip 110A, second semiconductor chip 110B, and connection pads 111 may be equally applied to descriptions of insulating layers 251, wiring layers 252, vias 253, first additional semiconductor chip 210A, second additional semiconductor chip 210B, and connection pads 211, respectively, unless specifically contradicted.

First additional semiconductor chips 210 may be stacked in the Z direction (Z) and attached to another first additional semiconductor chip 210 or the redistribution structure 150 with a first additional adhesive member 220. An overhang region OH2 of a first additional semiconductor chip 210 may be supported by a first additional support film 230. However, a first additional semiconductor chip 210 may include only a single semiconductor chip.

The first additional redistribution structure 250 may be connected to the redistribution structure 150 by a first additional conductive post 291 embedded in the first additional encapsulant 240 and connected to a first additional semiconductor chip 210 by a second conductive post 292.

On the first additional redistribution structure 250, a passivation layer 261, conductive pillars 262, and conductive bumps 263 may be disposed.

In addition, the descriptions of a semiconductor chip 110, an adhesive member 120, a support film 130, the encapsulant 140, the redistribution structure 150, the passivation layer 161, a conductive pillar 162, a conductive bump 163, and a conductive post 190 may be equally applied to descriptions of an additional semiconductor chip 210, an additional adhesive member 220, an additional support film 230, an additional encapsulant 240, an additional redistribution structure 250, a passivation layer 261, a conductive pillar 262, a conductive bump 263, and additional conductive posts 291 and 292, respectively, unless specifically contradicted.

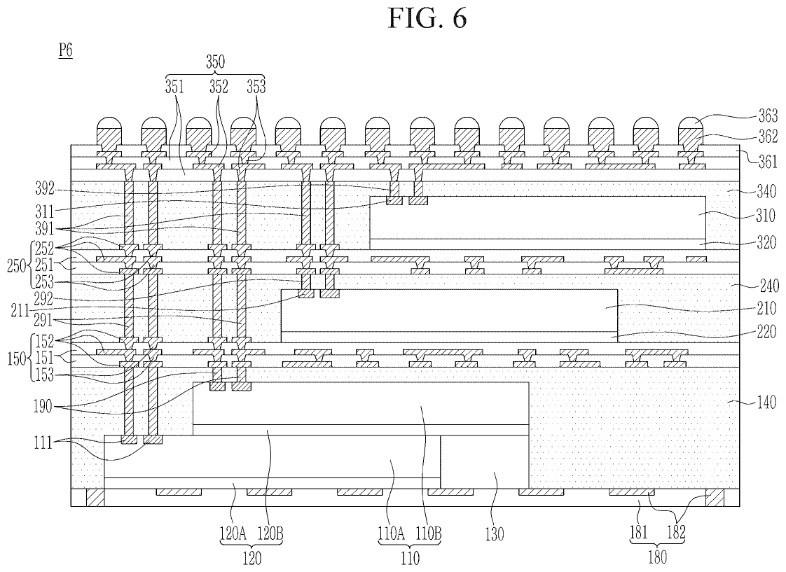

FIG. 6 is a cross-sectional view of a semiconductor package according to some embodiments.

As compared to the semiconductor package P5, a semiconductor package P6 may further include a second additional semiconductor chip 310 disposed on the first additional redistribution structure 250, a second additional encapsulant 340 which covers at least a portion of the second additional semiconductor chip 310, and a second additional redistribution structure 350 disposed on the second additional encapsulant 340.

The descriptions of insulating layers 151, wiring layers 152, vias 153, and connection pads 111 may be equally applied to descriptions of insulating layers 351, wiring layers 352, vias 353, and connection pads 311, respectively, unless specifically contradicted.

The second additional semiconductor chip 310 may be attached to the first additional redistribution structure 250 with a second additional adhesive member 320.

The second additional redistribution structure 350 may be connected to the first additional redistribution structure 250 by a third additional conductive post 391 embedded in the second additional encapsulant 340, and connected to the second additional semiconductor chip 310 by a fourth additional conductive post 392.

On the second additional redistribution structure 350, a passivation layer 361, conductive pillars 362, and conductive bumps 363 may be disposed.

In addition, the descriptions of a semiconductor chip 110, an adhesive member 120, the encapsulant 140, the redistribution structure 150, the passivation layer 161, a conductive pillar 162, a conductive bump 163, and a conductive post 190 may be equally applied to descriptions of the additional semiconductor chip 310, the additional adhesive member 320, the additional encapsulant 340, the additional redistribution structure 350, the passivation layer 361, a conductive pillar 362, a conductive bump 363, and the additional conductive posts 391 and 392, respectively, unless specifically contradicted.

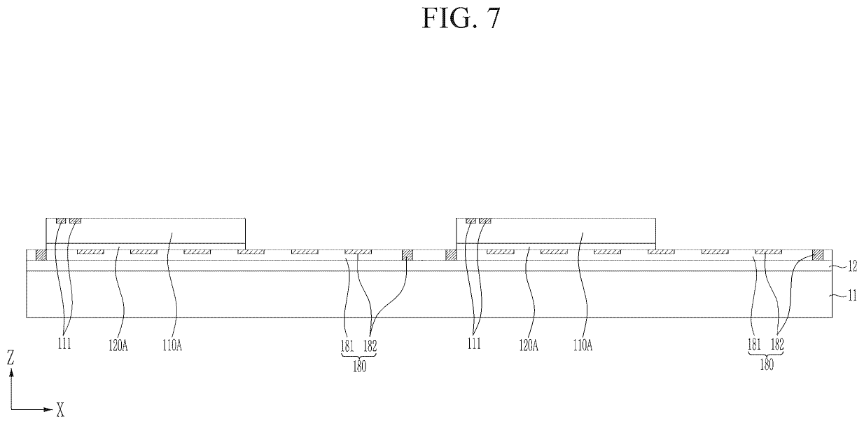

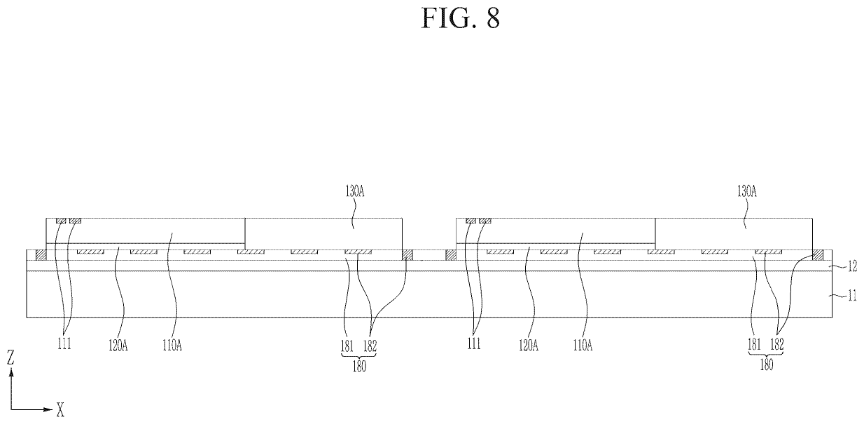

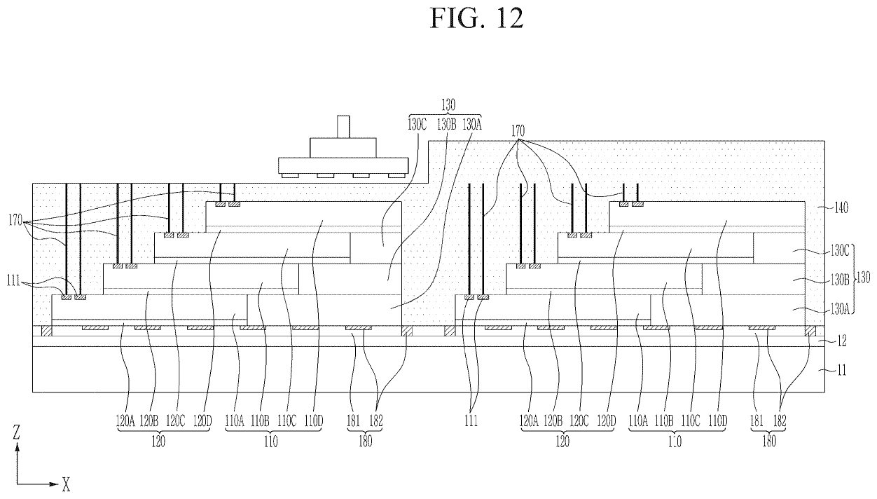

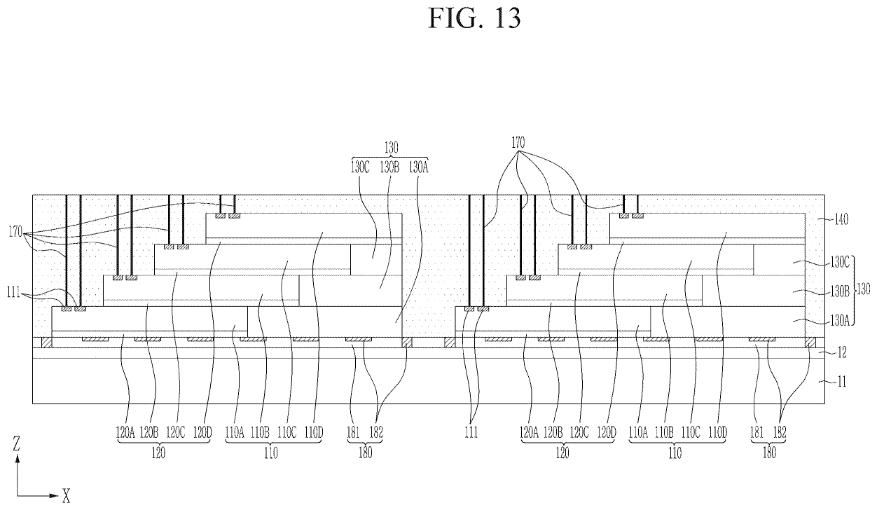

FIGS. 7 to 16 are views illustrating a process of manufacturing a semiconductor package according to some embodiments.

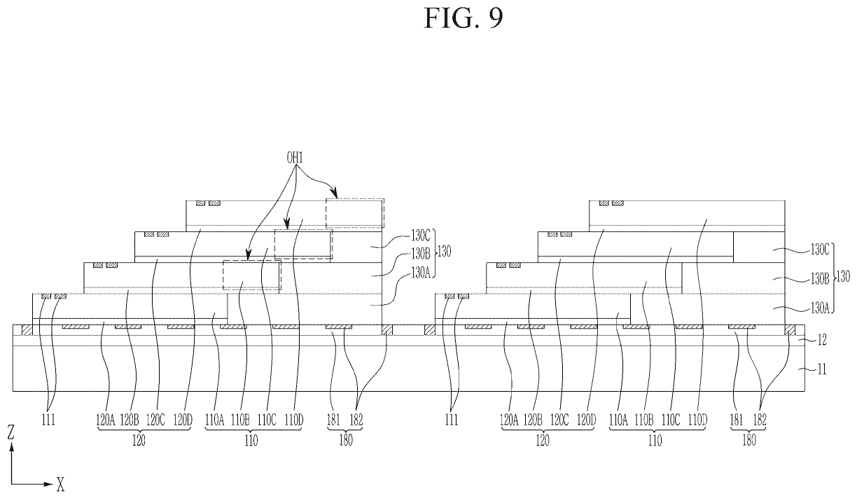

Referring to FIGS. 7 and 9 first, first, on a carrier substrate 11, the first semiconductor chip 110A may be disposed, and the first support film 130A is disposed side by side with the first semiconductor chip 110A. Further, on the first semiconductor chip 110A and the first support film 130A, the second semiconductor chip 110B and the second support film 130B are disposed side by side, and on the second semiconductor chip 110B and the second support film 130B, the third semiconductor chip 110C and the third support film 130C are disposed side by side, and then, on the third semiconductor chip 110C and the third support film 130C, the fourth semiconductor chip 110D is disposed.

The semiconductor package P1 may be manufactured at a wafer level, and on the carrier substrate 11, the plurality of semiconductor chips 110, each of which constitutes a separate semiconductor package, and the support films 130 may be disposed side by side.

The carrier substrate 11 may be a glass substrate, a silicon substrate, etc. On the carrier substrate 11, a release layer 12 for removing the carrier substrate 11 may be disposed. Further, on the release layer 12, the alignment structure 180 for providing the alignment positions of the semiconductor chips 110 may be formed.

The second semiconductor chip 110B may be disposed on the first semiconductor chip 110A so as to be misaligned with the first semiconductor chip 110A such that it has the overhang region OH1 which is supported by the first support film 130A, and the second support film 130B may be disposed side by side with the second semiconductor chip 110B on the first support film 130A. Similarly, the third semiconductor chip 110C may be disposed on the second semiconductor chip 110B so as to be misaligned with the second semiconductor chip 110B such that it has the overhang region OH1 which is supported by the second support film 130B, and the third support film 130C may be disposed side by side with the third semiconductor chip 110C on the second support film 130B. Further, the fourth semiconductor chip 110D may be disposed on the third semiconductor chip 110C so as to be misaligned with the third semiconductor chip 110C such that it has the overhang region OH1 which is supported by the third support film 130C.

Each semiconductor chip 110 may be attached to another component by an adhesive member 120. For example, the first semiconductor chip 110A may be attached to the upper surface of the carrier substrate 11 (to the alignment structure 180) with the first adhesive member 120A. Further, the second semiconductor chip 110B may be attached to the upper surfaces of the first semiconductor chip 110A and the first adhesive member 120A with the second adhesive member 120B. Furthermore, the third semiconductor chip 110C may be attached to the upper surfaces of the second semiconductor chip 110B and the second adhesive member 120B with the third adhesive member 120C. Moreover, the fourth semiconductor chip 110D may be attached to the upper surfaces of the third semiconductor chip 110C and the third adhesive member 120c with the fourth adhesive member 120d.

The thickness of each support film 130 may be equal to or larger than the sum of the thickness of a semiconductor chip 110 disposed side by side with the support film and the thickness of an adhesive member 120 in order to come into contact with the semiconductor chip 110 and support the overhang region OH1. For example, in the step of disposing the first support film 130A, the thickness of the first support film 130A may be equal to or larger than the sum of the thickness of the first semiconductor chip 110A and the thickness of the first adhesive member 120A. Further, in the step of disposing the second support film 130B, the thickness of the second support film 130B may be equal to or larger than the sum of the thickness of the second semiconductor chip 110B and the thickness of the second adhesive member 120B. Furthermore, in the step of disposing the third support film 130C, the thickness of the third support film 130C may be equal to or larger than the sum of the thickness of the third semiconductor chip 110C and the thickness of the third adhesive member 120C. Accordingly, the upper surface of each attached support film 130 may be positioned at the same level as that of the upper surface of a semiconductor chip 110 disposed side by side with the support film, or at a higher level than the upper surface of the semiconductor chip.

When the upper surface of an attached support film 130 is positioned at a higher level than the upper surface of a semiconductor chip 110 disposed side by side with the support film, the support film 130 may be pressed by another semiconductor chip 110 which is disposed on the support film. Accordingly, after being pressed by another semiconductor chip 110, the upper surface of the support film 130 may be positioned at the same level as that of the upper surface of the semiconductor chip 110 disposed side by side with the support film. For example, the second semiconductor chip 110B may press the first support film 130A such that the upper surface of the first semiconductor chip 110A and the upper surface of the first support film 130A are positioned at the same level, and the third semiconductor chip 110C may press the second support film 130B such that the upper surface of the second semiconductor chip 110B and the upper surface of the second support film 130B are positioned at the same level, and the fourth semiconductor chip 110D may press the third support film 130C such that the upper surface of the third semiconductor chip 110C and the upper surface of the third support film 130C are positioned at the same level.

Each support film 130 may have the property of adhering such that it can be attached directly to the upper surface of the alignment structure 180 or another support film 130. For example, the first adhesive member 120A, the second adhesive member 120B, and the third adhesive member 120C may be attached directly to the upper surface of the alignment structure 180, the upper surface of the first support film 130A, and the upper surface of the second support film 130B, respectively.

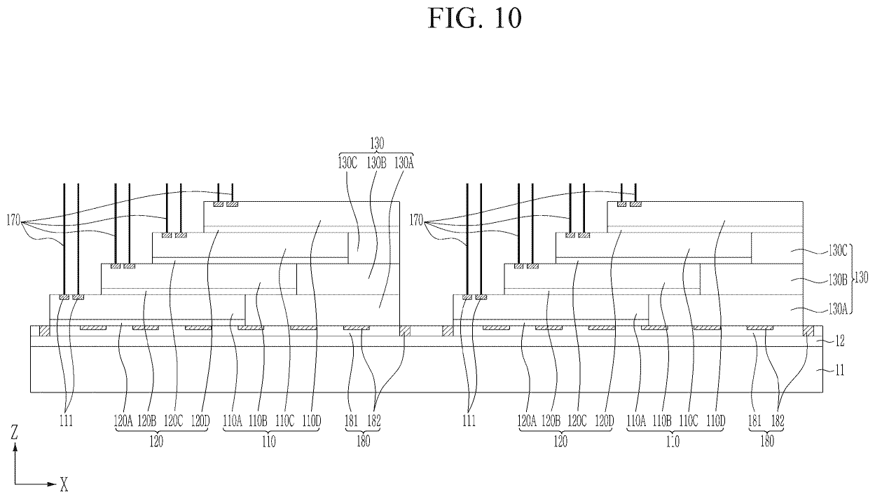

Next, referring to FIG. 10, the conductive wires 170 are connected to the connection pads 111 of the individual semiconductor chips 110. Each conductive wire 170 may be a vertical conductive wire extending in the Z direction (Z).

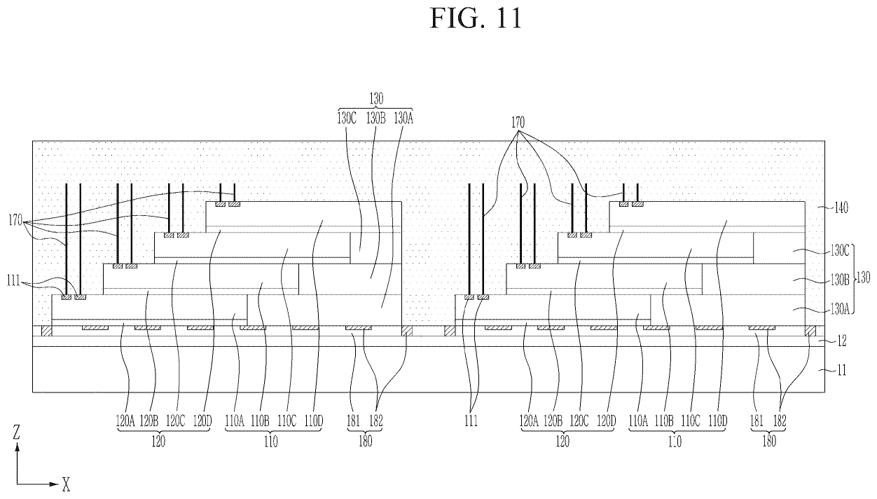

Next, referring to FIGS. 11 to 13, the semiconductor chips 110, the support films 130, and the adhesive members 120 are encapsulated by the encapsulant 140, and the encapsulant 140 can be ground to expose the conductive wires 170. During the grinding on the encapsulant 140, some portions of the conductive wires may be ground together.

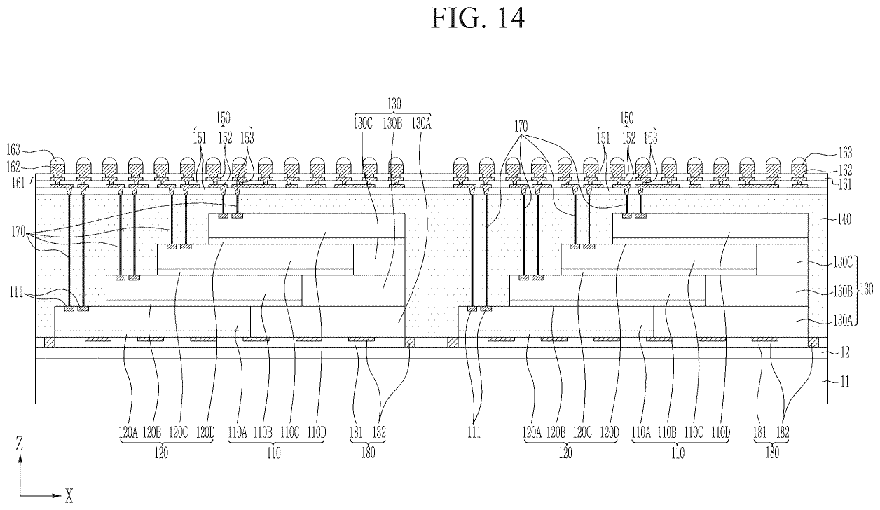

Next, referring to FIG. 14, on the encapsulant 140, the redistribution structure 150 can be formed so as to be electrically connected to the semiconductor chips 110. The redistribution structure may be formed by sequentially forming an insulating layer 151, vias 153, and a wiring layer 152. On the redistribution structure 150, a passivation layer 161, a conductive pillar 162, and a conductive bump 163 may be additionally formed if necessary.

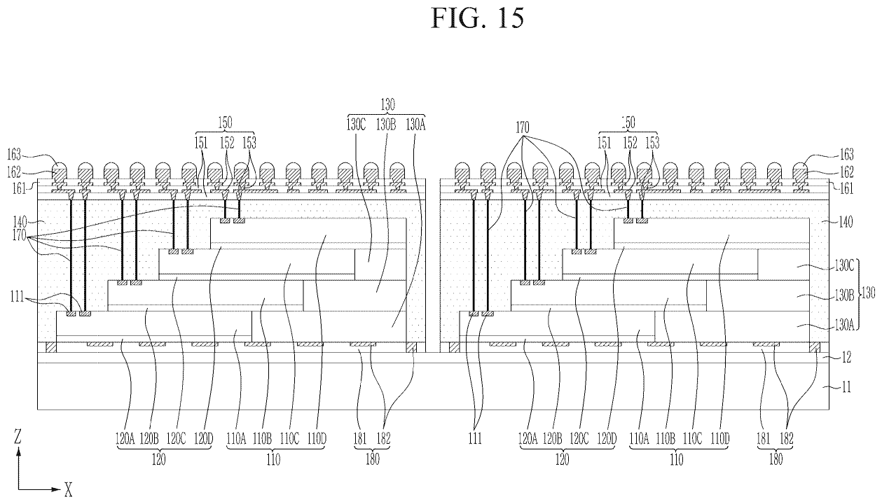

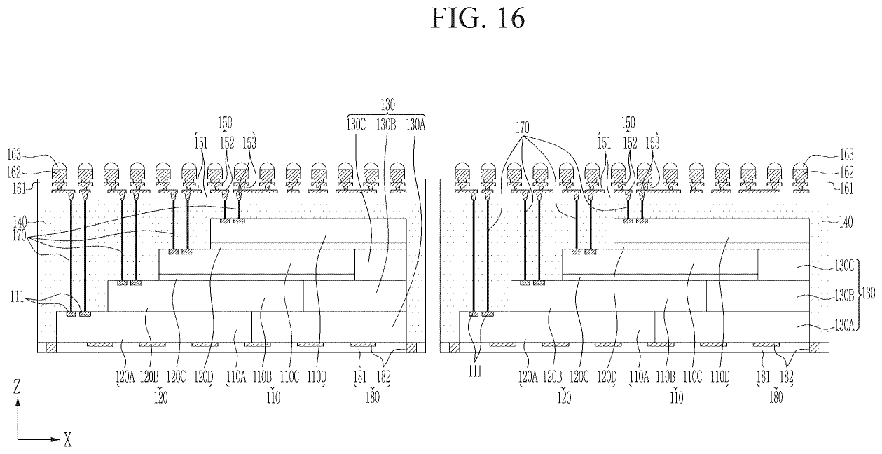

Next, referring to FIGS. 15 and 16, the redistribution structure 150, the encapsulant 140, and the alignment structure 180 may be sawed along the regions between the semiconductor chips 110 with a blade, a laser, etc., and the carrier substrate 11 and the release layer 12 may be removed, whereby individual semiconductor packages may be formed.

While this disclosure has been described in connection with what is presently considered to be practical embodiments, it is to be understood that the disclosure is not limited to the disclosed embodiments. On the contrary, it is intended to cover various modifications and equivalent arrangements included within the spirit and scope of the appended claims.

Further, the embodiments of the present disclosure are not independent from one another, and may be implemented in combination with one another. Accordingly, it will be appreciated that forms which are implemented by combining the embodiments of the present disclosure are also included in the present disclosure.

What is claimed is:

1. A semiconductor package comprising:
a first semiconductor chip;
a first support film that is disposed side by side with the first semiconductor chip;
a second semiconductor chip that is disposed on the first semiconductor chip so as to be misaligned with the first semiconductor chip, wherein the second semiconductor chip includes a first overhang region which is supported by the first support film;
a second support film that is disposed on the first support film side by side with the second semiconductor chip;
an encapsulant that covers at least a portion of each of the first semiconductor chip, the second semiconductor chip, the first support film, and the second support film; and
a redistribution structure that is disposed on the encapsulant and electrically connected to the first semiconductor chip and the second semiconductor chip.

2. The semiconductor package of claim 1, further comprising:
a third semiconductor chip that is disposed on the second semiconductor chip so as to be misaligned with the second semiconductor chip and includes a second overhang region which is supported by the second support film.

3. The semiconductor package of claim 1, wherein:
a width of the first support film is wider than a width of the second support film.

4. The semiconductor package of claim 1, wherein:
at least one of the first support film and the second support film is a multi-layer film including a plurality of layers stacked.

5. The semiconductor package of claim 1, wherein:
at least one of the first support film and the second support film includes Ajinomoto build-up film (ABF).

6. The semiconductor package of claim 1, wherein:
the first semiconductor chip includes a first connection pad disposed on an upper surface of the first semiconductor chip,
the second semiconductor chip includes a second connection pad disposed on an upper surface of the second semiconductor chip, and
the second semiconductor chip is disposed on the upper surface of the first semiconductor chip so as to be misaligned with the first semiconductor chip such that the first connection pad is exposed.

7. The semiconductor package of claim 6, wherein:
the redistribution structure faces the upper surfaces of the first semiconductor chip and the second semiconductor chip, and
the semiconductor package further includes conductive wires which are embedded in the encapsulant and electrically connect the first connection pad and the second connection pad to the redistribution structure, respectively.

8. The semiconductor package of claim 6, wherein:
the redistribution structure faces the upper surfaces of the first semiconductor chip and the second semiconductor chip, and
the semiconductor package further includes conductive posts that are embedded in the encapsulant and electrically connect the first connection pad and the second connection pad to the redistribution structure, respectively.

9. The semiconductor package of claim 6, wherein:
the redistribution structure faces lower surfaces of the first semiconductor chip and the second semiconductor chip, and
the semiconductor package further includes conductive wires which are embedded in the encapsulant and electrically connect the first connection pad and the second connection pad to the redistribution structure, respectively.

10. The semiconductor package of claim 1, further comprising:
conductive bumps that are disposed on the redistribution structure.

11. A semiconductor package comprising:
a first semiconductor chip;
a first adhesive member that is attached to a lower surface of the first semiconductor chip;
a second semiconductor chip that is disposed on an upper surface of the first semiconductor chip so as to be misaligned with the first semiconductor chip and includes an overhang region protruding outwardly from the first semiconductor chip;
a support film that has a lower surface coplanar with a lower surface of the first adhesive member and supports the overhang region of the second semiconductor chip;
a second adhesive member that is disposed between the first semiconductor chip and the second semiconductor chip and that attaches the second semiconductor chip to the first semiconductor chip and the support film;
a first encapsulant that covers at least a portion of each of the first semiconductor chip and the second semiconductor chip; and
a first redistribution structure that is disposed on the first encapsulant and is electrically connected to each of the first semiconductor chip and the second semiconductor chip.

12. The semiconductor package of claim 11, wherein:
a thickness of the support film is within a range from 40 μm to 70 μm.

13. The semiconductor package of claim 11, wherein:
a thickness of the first semiconductor chip is within a range from 35 μm to 55 μm.

14. The semiconductor package of claim 11, wherein:
a thickness of the first adhesive member is within a range from 5 μm to μm.

15. The semiconductor package of claim 11, further comprising:
a third semiconductor chip that is disposed on the first redistribution structure;
a second encapsulant that covers at least a portion of the third semiconductor chip; and
a second redistribution structure that is disposed on the second encapsulant and electrically connected to the third semiconductor chip and the first redistribution structure.

16. A semiconductor package comprising:
a first semiconductor chip;
a first support film that is disposed laterally adjacent to the first semiconductor chip;
a second semiconductor chip that is disposed in part on the first semiconductor chip and in part on the first support film;
a second support film that is disposed laterally adjacent to the second semiconductor chip; and
a first wiring layer that is electrically connected to the first semiconductor chip and a second wiring layer that is electrically connected to the second semiconductor chip.

17. The semiconductor package of claim 16, further comprising:
a third semiconductor chip that is disposed in part on the second semiconductor chip and in part on the second support film.

18. The semiconductor package of claim 16, wherein:
the first and second wiring layers are formed in a redistribution structure.

19. The semiconductor package of claim 18, wherein:
the second semiconductor chip is configured to press the first support film.

20. The semiconductor package of claim 16, wherein:
the second support film is attached to the first support film.
